(19) United States
(12) Patent Application Publication
(10) Pub. No.: US 2010/0221670 A1
(43) Pub. Date: Sep. 2, 2010

(54) PATTERN FORMATION METHOD

(75) Inventor: Atsushi MAEKAWA, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/713,662

(22) Filed: Feb. 26, 2010

(30) Foreign Application Priority Data
Feb. 27, 2009 (JP) 2009-046057

(51) Int. Cl. G03F 7/20

(52) U.S. Cl. 430/323; 430/322

(57) ABSTRACT

A method for forming a finer hole or line pattern including the step of sequentially depositing a first mask layer (3) and a first ARL (4) on a first layer (2) and patterning the first ARL; the step of sequentially depositing a second mask layer (6) and a second ARL (7) and patterning the second ARL; the step of removing the mask carbon layer by using the second ARL as a mask; the step of removing the first mask layer by using the second ARL and the exposed first ARL as masks; and removing the first layer by using the remaining first and second mask layers as masks.

### BACKGROUND OF THE INVENTION

1. Field of the Invention

The present invention relates to a pattern formation method including a hole or line pattern formation step using a hard mask including a stacked structure of a layer including carbon as the main component and an anti-reflecting layer (hereinafter referred to as an ARL).

2. Description of the Related Art

In order to provide high-performance semiconductor devices, methods for easily forming a pattern of holes or lines in the desired shape, even with the progress of miniaturization, are required.

Methods for obtaining a pattern in the desired shape by the overlap of patterns formed on a semiconductor substrate using two photomasks are known as one technique for solving such requirement (JP 2002-520875T (WO00/04571) and JP 2007-027742A).

In JP 2002-520875T, a combination of the pattern of a first formed hard mask and the pattern of a subsequently formed photoresist layer finally forms a pattern of holes.

JP 2007-027742A is characterized in that a stacked mask of a first hard mask and a second hard mask is used and that the first hard mask and the second hard mask are a combination of an oxide film and a nitride film with etching properties exclusive of each other.

However, in recent years, with further progress of miniaturization, it has been difficult to perform dry etching, directly using the pattern of a photoresist layer as a mask. This is because in order to accurately form the pattern of a photoresist layer for fine processing with high resolution properties in the desired shape, the photoresist thickness needs to be as thin as possible, while the etching resistance is insufficient.

Also, the etching resistance can be increased by adding a substance, such as silicon, to the photoresist layer, but generally, the resolution performance of such a photoresist, to which an additive is added, decreases, and therefore, the formation of a fine pattern is difficult.

Also, in both JP 2002-520875T and JP 2007-027742A, the pattern of a new photoresist layer is formed on the first formed hard mask as it is. Therefore, a difference in level due to the hard mask layer is present, and the formation of a fine pattern of the photoresist layer is difficult. This is because due to the effect of the difference in level in the base, the thickness of the photoresist layer is locally thick, and it is difficult to perform uniform pattern formation by exposure.

### SUMMARY

In view of such circumstances, the present invention provides a manufacturing method for forming a finer hole or line pattern-more easily than conventional manufacturing methods.

A pattern formation method in one exemplary embodiment includes:

forming a first mask layer on a first layer;

forming a first anti-reflecting layer on the first mask layer;

forming a first photoresist pattern on the first anti-reflecting layer;

forming a pattern of the first anti-reflecting layer, using the first photoresist pattern as a mask;

forming a second mask layer so as to cover the first anti-reflecting layer pattern and the first mask layer;

forming a second anti-reflecting layer on the second mask layer;

forming a second photoresist pattern on the second anti-reflecting layer;

forming the second anti-reflecting layer in a pattern comprising an opening region at least not overlapping the first anti-reflecting layer pattern, using the second photoresist pattern as a mask;

removing the second mask layer, using the second anti-reflecting layer pattern as a mask;

removing the first mask layer by using the second anti-reflecting layer pattern and the first anti-reflecting layer pattern exposed by removal of the second mask layer as masks; and

removing the first layer by using the remaining first and second mask layers as masks.

The first mask layer and the second mask layer preferably include carbon.

Also, a pattern formation method in another exemplary embodiment is a method using carbon layers as the first and second mask layers. Moreover, a pattern formation method in further exemplary embodiment is a method using a carbon layer as the first mask layer and an organic coating layer as the second carbon layer.

By forming the pattern of holes or lines by the combinations of the hard masks (the mask layer and the ARL) formed in twice, the photoresist layer used for patterning can be used in the state of a thin layer with high resolution. Also, the difference in level in the base is reduced in the photoresist layer pattern formation for the second time, and therefore, the patterning of the photoresist layer for the second time is easier than conventional ones. Therefore, a fine pattern can be easily formed.

Also, when the stacked layers of the organic coating layer and the ARL is used as the hard mask for the second time, the effect of reducing the difference in level in the base is improved, and the surface is further flattened. Therefore, further miniaturization is possible.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic plan view of a hole pattern to be formed, according to a first exemplary embodiment;

FIG. 2A-FIG. 2D are cross-sectional views after the patterning of a first photoresist layer according to the first exemplary embodiment;

FIG. 3 is a plan view for explaining a first photomask used for the patterning of the first photoresist layer according to the first exemplary embodiment;

FIG. 4A-FIG. 4D are cross-sectional views after the patterning of a first ARL according to the first exemplary embodiment;

FIG. 5A-FIG. 5D are cross-sectional views after the forming of a second hard mask layer according to the first exemplary embodiment;

FIG. 6A-FIG. 6D are cross-sectional views after the patterning of a second photoresist layer according to the first exemplary embodiment;

FIG. 7 is a plan view for explaining a second photomask used for the patterning of the second photoresist layer according to the first exemplary embodiment;

FIG. 8A-FIG. 8D are cross-sectional views after the patterning of a second ARL according to the first exemplary embodiment;

FIG. 9A-FIG. 9D are cross-sectional views after the patterning of first and second carbon layers according to the first exemplary embodiment;

FIG. 10A-FIG. 10D are cross-sectional views immediately after the etching of a layer to be processed, according to the first exemplary embodiment;

FIG. 11A-FIG. 11D are cross-sectional views after the removal of the first carbon layer according to the first exemplary embodiment;

FIG. 12 is a schematic plan view of a wiring layer pattern to be formed, according to a second exemplary embodiment;

FIG. 13 is a cross-sectional view after the lamination of a first hard mask layer according to the second exemplary embodiment;

FIG. 14 is a plan view for explaining a first photomask used for the patterning of a first photoresist layer according to the second exemplary embodiment;

FIG. 15 is a cross-sectional view after the patterning of the first photoresist layer according to the second exemplary embodiment;

FIG. 16 is a cross-sectional view after the patterning of a first ARL according to the second exemplary embodiment;

FIG. 17 is a cross-sectional view after the patterning of a second photoresist layer according to the second exemplary embodiment;

FIG. 18 is a plan view for explaining a second photomask used for the patterning of the second photoresist layer according to the second exemplary embodiment;

FIG. 19 is a cross-sectional view after the patterning of a second ARL according to the second exemplary embodiment;

FIG. 20 is a cross-sectional view after the patterning of first and second carbon layers according to the second exemplary embodiment;

FIG. 21 is a cross-sectional view immediately after the etching of a layer to be processed, according to the second exemplary embodiment; and

FIG. 22 is a cross-sectional view after wiring layer formation according to the second exemplary embodiment.

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

The present invention can be applied to both hole (opening) patterns for forming contact plugs and capacitors of a DRAM device, and line patterns for forming wiring layers and the like.

### First Exemplary Embodiment

First, a manufacturing method when a hole pattern is formed will be described with reference to the drawings.

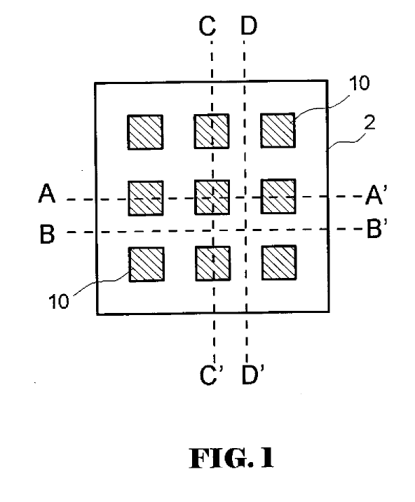

FIG. 1 is a plan view showing a hole pattern to be formed. A plurality of holes 10 (nine in FIG. 1 as an example) are formed in interlayer insulating layer 2 as a first layer to be processed, provided on a semiconductor substrate (not shown). The number of holes is one example and is not particularly limited.

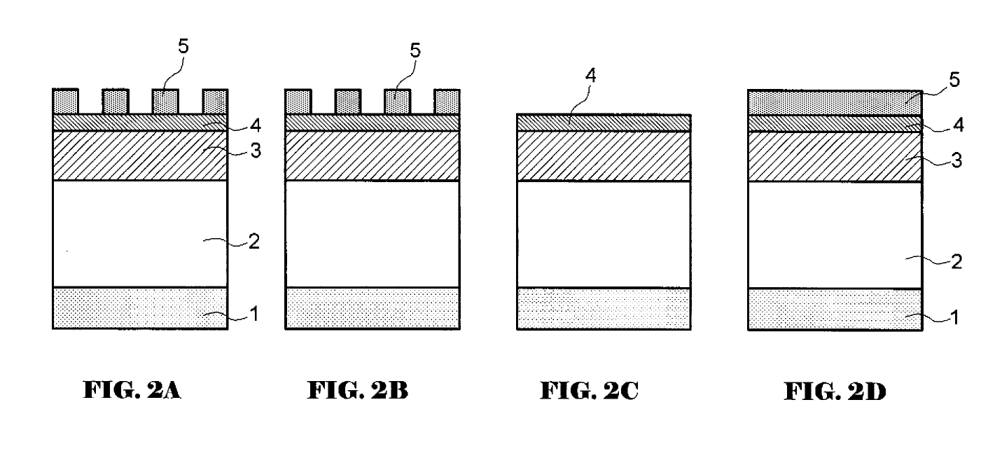

Cross-sectional views along lines A-A′, B-B′, C-C′, and D-D′ in FIG. 1 are shown as cross-sectional views in FIG. 2A-FIG. 2D and the subsequent figures.

First, as shown in FIG. 2A-FIG. 2D, interlayer insulating layer 2, such as a silicon oxide layer (SiO₂), with a thickness of about 1000 nm is deposited on semiconductor substrate 1 by CVD or the like.

First carbon layer 3 with a thickness of about 600 nm, and first ARL 4 with a thickness of about 50 nm are sequentially formed on interlayer insulating layer 2.

Specifically, an amorphous carbon layer can be used as the carbon layer. The amorphous carbon layer is obtained by performing deposition by a plasma CVD apparatus, using hydrocarbon, such as methane (CH₄), acetylene (C₂H₂), and ethane (C₂H₅), as the main raw material. Also, a stacked layer having a structure in which a silicon oxide film is deposited on a silicon oxynitride (SiON) film can be used as the ARL.

The ARL suppresses the effect of reflected light from the lower layer in patterning a photoresist layer using an exposure apparatus, and in the present invention, the ARL also functions as a hard mask in etching. Therefore, the ARL preferably includes a material for which a high etching rate ratio (selection ratio) to the carbon layer can be set in dry etching, like a silicon oxynitride layer.

First photoresist layer 5 is coated on first ARL 4, and patterning is performed using photolithography technique. For example, a chemically-amplified photoresist with photosensitivity to ArF excimer laser light (wavelength: 193 nm) can be used for the first photoresist layer.

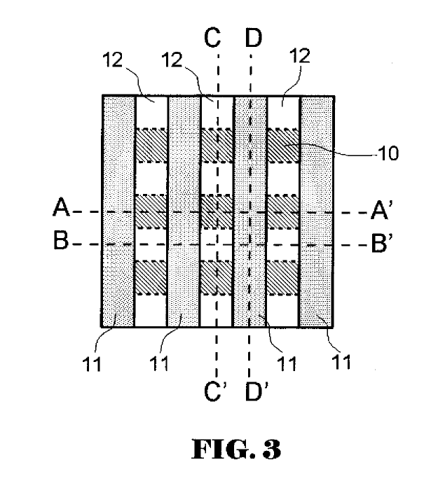

The layout of a first photomask used for the patterning of first photoresist layer 5 will be described with reference to a plan view in FIG. 3.

In FIG. 3, places where holes 10 are formed in a subsequent step are shown by hatch surrounded by a broken line for reference (a pattern of holes 10 itself is not present on the first photomask).

Reference numeral 11 denotes light-blocking regions of the first photomask, which are formed in a plurality of strip-shaped patterns extending in the direction of D-D′. Reference numeral 12 denotes transmissive regions (transparent regions) of the first photomask, which are formed in a plurality of strip-shaped patterns extending in the direction of C-C′. The widths of light-blocking region 11 and transmissive region 12 are defined by the layout of holes 10 and need not necessarily be equal.

By performing exposure using the first photomask and development, photoresist layer 5 at positions corresponding to light-blocking regions 11 remains, and photoresist layer 5 at positions corresponding to transmissive regions 12 is removed, thereby, the pattern of photoresist layer 5 shown in FIG. 2A-FIG. 2D is formed.

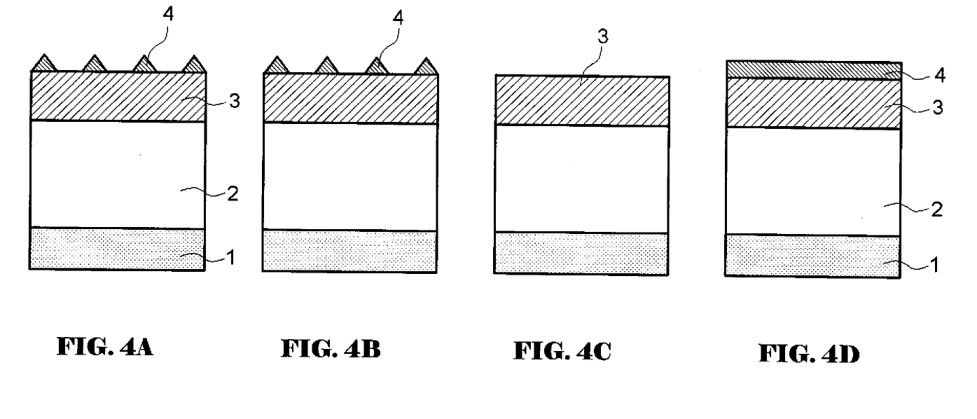

Next, dry etching is performed using the pattern of photoresist layer 5 as a mask, and the patterning of first ARL 4 is performed, as shown in FIG. 4A-FIG. 4D. At this time, by decreasing the etching selection ratio between first ARL 4 and first photoresist layer 5, first ARL 4 can remain in tapered shapes, as shown in FIG. 4A-FIG. 4D. Specifically, dry etching may be performed using a gas mixture of CF₄, O₂, and Ar at a flow rate ratio of about 3:1:5 and using a parallel plate type plasma etching apparatus. First ARL 4 need not be in complete tapered shapes, and only portions near the upper surface of first ARL 4 may be tapered.

In this etching, the etching of first photoresist layer 5 also proceeds, and part of first photoresist layer 5 is removed. The remaining first photoresist layer 5 may be removed by stripping treatment using a chemical solution, such as a sulfuric acid-hydrogen peroxide mixture (H₂SO₄/H₂O₂).

In this manner, first photoresist layer 5 may have mask resistance enough to etch first ARL 4. Therefore, by making the photoresist layer thinner, even a fine pattern (for example, the width of the remaining portion is 50 nm or less) can be easily formed.

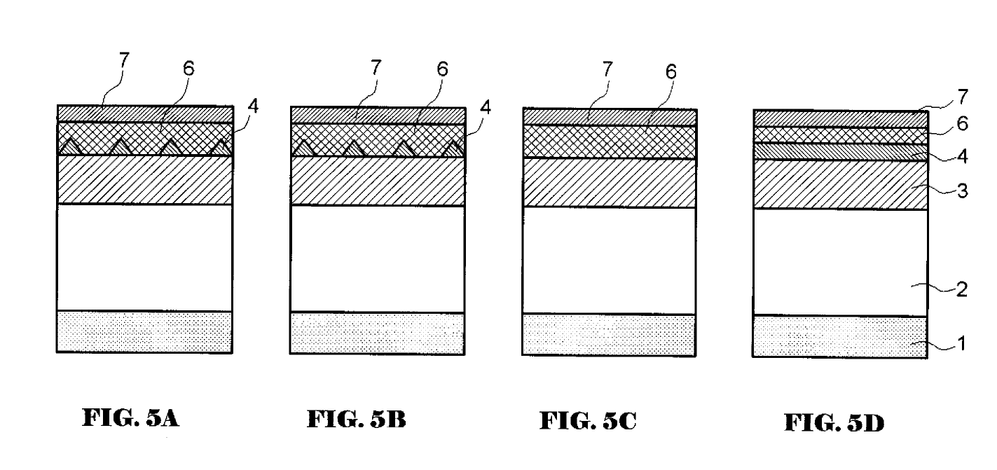

Next, as shown in FIG. 5A-FIG. 5D, second carbon layer 6 with a thickness of about 100 nm is deposited so as to cover first ARL 4. By forming at least the vicinity of the upper surface of first ARL 4 in tapered shapes, second carbon layer 6 can be easily deposited so as to suppress the formation of cavities (voids) and the like and fill the space portions of adjacent first ARL 4. The second carbon layer may be formed of the same material as the first carbon layer.

Second ARL 7 with a thickness of about 50 nm is deposited on second carbon layer 6. The second ARL may be formed of the same material as the first ARL.

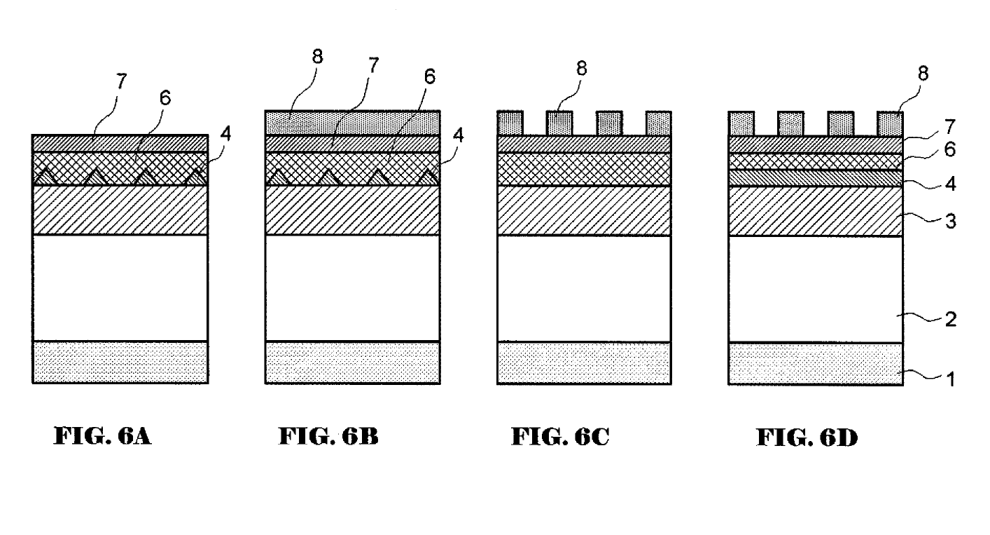

Next, as shown in FIG. 6A-FIG. 6D, second photoresist layer 8 is coated on second ARL 7, and patterning is performed using photolithography technique. For example, a chemically-amplified photoresist with photosensitivity to ArF excimer laser light can be used for second photoresist layer 8.

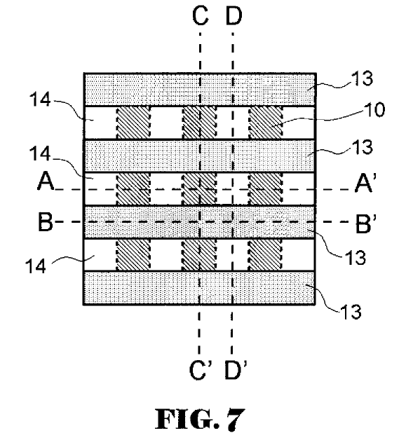

The layout of a second photomask used for the patterning of second photoresist layer 8 will be described with reference to a plan view in FIG. 7.

In FIG. 7, places where holes 10 are formed in a subsequent step are shown by hatch surrounded by a broken line for reference (the pattern of holes 10 itself is not present on the second photomask).

Reference numeral 13 denotes the light-blocking regions of the second photomask, which are formed in a plurality of strip-shaped patterns extending in the direction of B-B′. Reference numeral 14 denotes the transmissive regions of the second photomask, which are formed in a plurality of strip-shaped patterns extending in the direction of A-A′. The widths of light-blocking region 13 and transmissive region 14 are defined by the layout of holes 10 and need not necessarily be equal. Holes 10 are formed in portions where the transmissive region 12 of the first photomask (FIG. 3) and the transmissive region 14 of the second photomask (FIG. 7) cross each other. In other words, the second photomask is located so that in portions corresponding to holes 10, opening regions not overlapping the first ARL pattern can be formed in the second ARL.

By performing exposure using the second photomask and development, second photoresist layer 8 at positions corresponding to light-blocking regions 13 remains, and second photoresist layer 8 at positions corresponding to transmissive regions 14 is removed, thereby, second photoresist layer 8 shown in FIG. 6A-FIG. 6D is formed in a linear pattern crossing the linear pattern of first ARL 4.

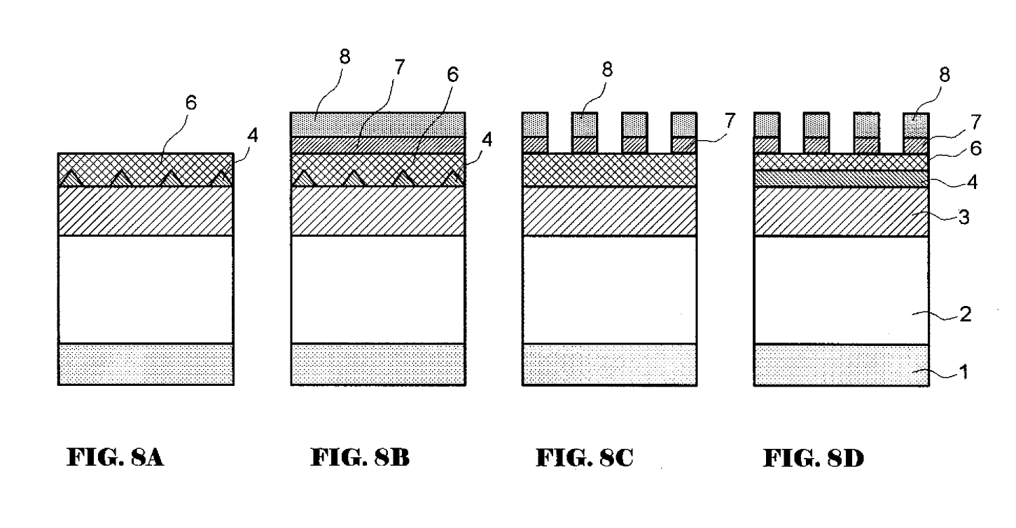

Next, as shown in FIG. 8A-FIG. 8D, dry etching is performed using the pattern of second photoresist layer 8 as a mask, and the patterning of second ARL 7 is performed. The second ARL need not necessarily be processed into tapered shapes, and therefore, etching may be performed under conditions in which the etching selection ratio between second ARL 7 and second photoresist layer 8 is increased. Specifically, etching may be performed by a parallel plate type plasma etching apparatus, using a CF₄ gas. Second photoresist layer 8 may remain because it is removed in a subsequent step, or it may be removed at this point of time, as in first photoresist layer 5.

In this manner, second photoresist layer 8 also may have mask resistance enough to etch second ARL 7. Therefore, by making the photoresist layer thinner, even a fine pattern (for example, the width of the remaining portion is 50 nm or less) can be easily formed.

Also, the difference in level in the base is reduced by the deposition of second carbon layer 6, and therefore, the pattern formation of second photoresist layer 8 is easy.

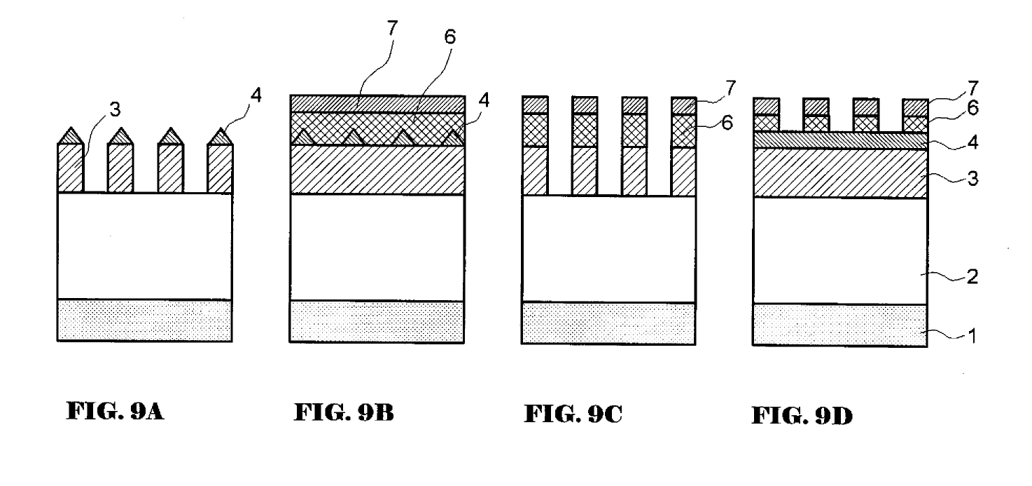

Next, dry etching is performed under conditions in which the carbon layers can be selectively removed using the first and second ARLs as masks, to remove second carbon layer 6 and first carbon layer 3, as shown in FIG. 9A-FIG. 9D. As shown in FIG. 9A, with first ARL 4 serving as a mask in the portions of first ARL 4 exposed by removing second carbon layer 6, first carbon layer 3 in the lower layer is removed.

Specifically, the carbon layers can be selectively etched using the ARLs as masks, by using a parallel plate type plasma etching apparatus and setting the following conditions (the etching rate selection ratio is about 50).

O₂ flow rate=100 sccm

Ar flow rate=100 sccm

pressure=1.33 Pa (10 mTorr)

power=500 W

When second photoresist layer 8 remains, the etching of the photoresist layer also proceeds with the removal of the carbon layers in this etching, and therefore, second photoresist layer 8 is also simultaneously removed.

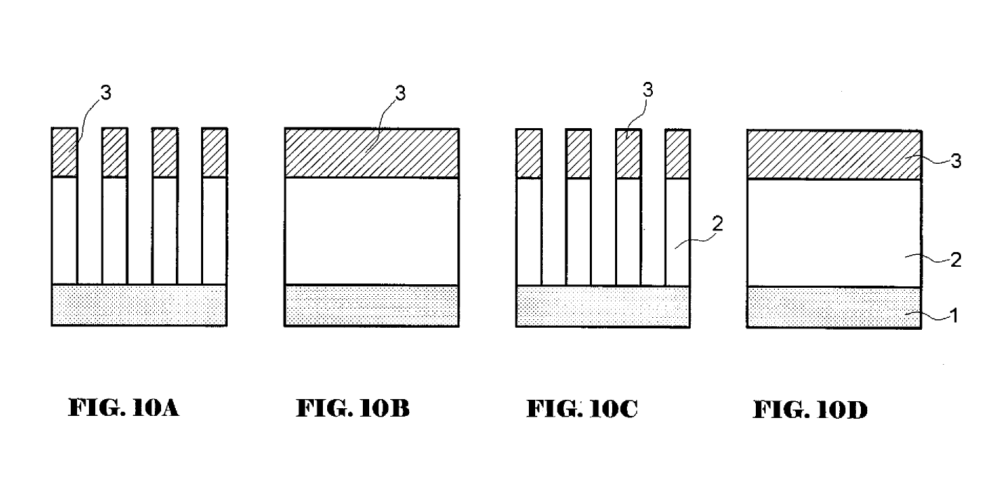

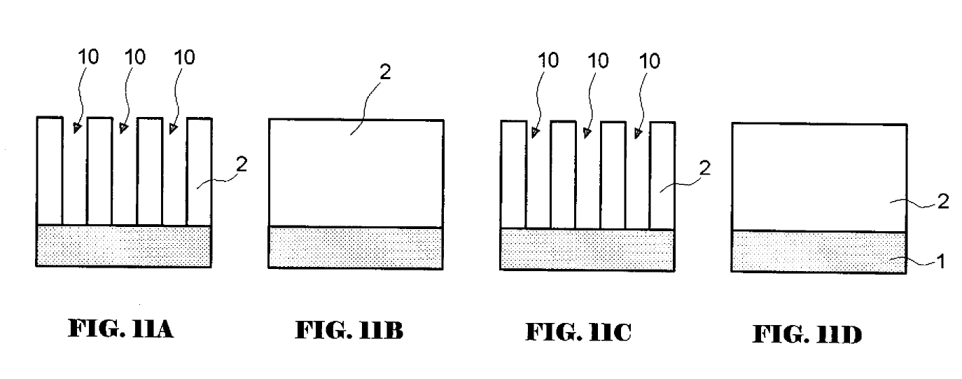

Next, as shown in FIG. 10A-FIG. 10D, the etching of interlayer insulating layer 2 is performed using the first and second carbon layers as masks.

Specifically, anisotropic dry etching may be performed, adding an additive gas, such as O₂, N₂, Ar, and Xe, to at least one gas selected from the group of fluorocarbon gases, such as C₄F₈, C₅F₈, C₄F₆, CHF₃, and CH₂F₂.

In this etching, the etching of the ARLs also proceeds, and therefore, first ARL 4 and second ARL 7 are also removed. Also, the etching of second carbon layer 6 also proceeds gradually at a point of time when second ARL 7 is removed, in FIG. 9B and FIG. 9D. Since the thickness of second carbon layer 6 during deposition is thin, second carbon layer 6 is finally entirely removed, and first ARL 4 is exposed. First ARL 4 is also finally entirely removed, and only first carbon layer 3 remains as a mask.

Next, when the remaining first carbon layer 3 is removed by plasma ashing using an O₂ gas, holes 10 are formed in interlayer insulating layer 2, as shown in FIG. 11A-FIG. 11D.

As described above, in the present invention, the pattern of holes can be formed by the combinations of the hard masks (the carbon layer and the ARL) formed in twice. At this time, the photoresist layer used for the pattern formation of the hard mask may have only resistance to the etching of the ARL in the upper layer. Therefore, for the photoresist layer for fine processing that can be exposed by an ArF light source or the like, it is not necessary to form a thicker layer or add Si or the like to increase etching resistance, and the photoresist layer can be used with high resolution. Also, the difference in level in the base is reduced in the photoresist layer pattern formation for the second time, and therefore, the patterning of the photoresist layer is easier than conventional ones. Therefore, it can become easily to form a pattern finer than conventional ones.

The formation method of the present invention is suitably applied in forming a pattern in which a plurality of holes are located according to a predetermined rule, for example, for forming holes to embed capacitor electrodes therein in the memory cells of a DRAM device.

The pattern of the first photomask and the pattern of the second photomask need not necessarily be orthogonal to each other and may cross each other at a predetermined angle other than a right angle.

### [Modification of First Exemplary Embodiment]

Operations are performed as in the first exemplary embodiment up to the patterning of the first ARL (FIG. 4A-FIG. 4D).

Next, instead of second carbon layer 6, an organic layer (referred to as an organic coating layer) including carbon as the main component, which can be formed by coating, and which can be removed by oxygen plasma or the like, as in the carbon layer, is formed.

Specifically, materials including a polyhydroxystyrene resin as the main component, to which an organic solvent, such as PGMEA (propylene glycol monomethyl ether acetate) and ethyl lactate, is added, can be used. Also, organic layers containing silicon can be used. Specifically, organic polysiloxane layers in which polysiloxane is added to a novolak resin or an acryl polymer can be used.

These organic layers are applied by spin coating, and then baked at a temperature of about 85 to 200° C. to be cured. Then, second ARL 7 is formed on the formed organic coating layer, as in the first exemplary embodiment.

These organic coating layers can be etched as in the carbon layer, and function as a hard mask. Also, the etching selection ratio to the ARL can be high as in the carbon layer.

Also, since the organic coating layer is formed by coating, the flatness of the surface is improved, compared with the carbon layer. Therefore, when second photoresist layer 8 is patterned using an exposure apparatus, the thickness of the applied photoresist layer is uniform, and a manufacturing margin, such as focal depth, increases. Therefore, the pattern can be more easily formed with good precision.

### Second Exemplary Embodiment

A case where the present invention is applied to the formation of wiring layers (a line pattern) obtained by patterning a metal layer will be described.

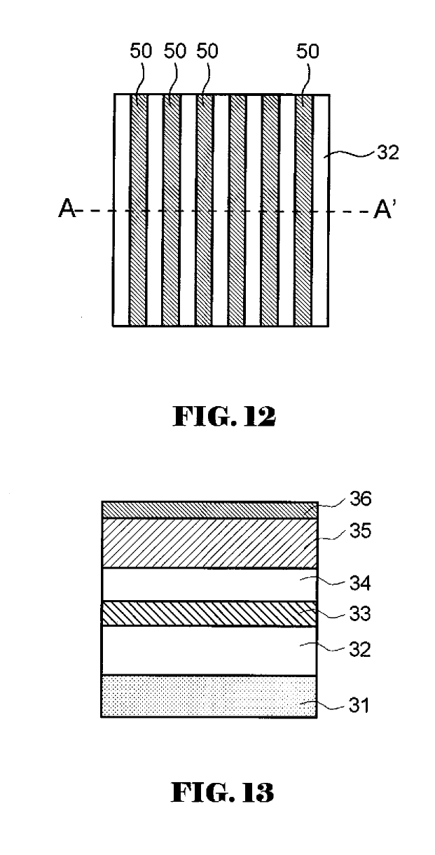

FIG. 12 is a plan view showing the layout of a line pattern to be formed. A plurality of wiring layers 50 (six in FIG. 12 as an example) are formed on interlayer insulating layer 32 provided on a semiconductor substrate (not shown). The number of wiring layers is one example and is not particularly limited.

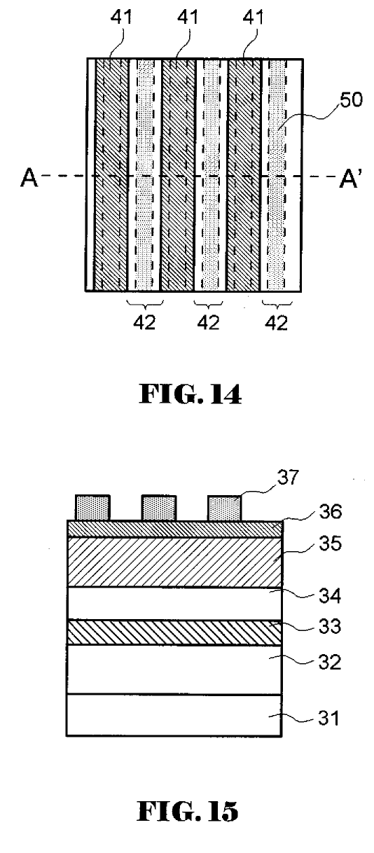

A cross-sectional view along line A-A′ in FIG. 12 is shown as cross-sectional views in FIG. 13 and the subsequent figures.

First, as shown in FIG. 13, interlayer insulating layer 32, such as a silicon oxide layer (SiO₂), with a thickness of about 100 nm is deposited on semiconductor substrate 31 by CVD or the like, and metal layer 33 desired to be processed, such as tungsten (W), with a thickness of about 80 nm is deposited on interlayer insulating layer 32.

Silicon oxide layer 34 used as a first layer, which will become a hard mask for processing metal layer 33, with a thickness of about 100 nm, is deposited on metal layer 33 by CVD or the like. First carbon layer 35 with a thickness of about 600 nm, and first ARL 36 with a thickness of about 50 nm are sequentially formed on silicon oxide layer 34.

First ARL 36 is coated with first photoresist layer 37, and patterning is performed using photolithography technique. For example, a chemically-amplified photoresist with photosensitivity to ArF excimer laser light can be used for first photoresist layer 37.

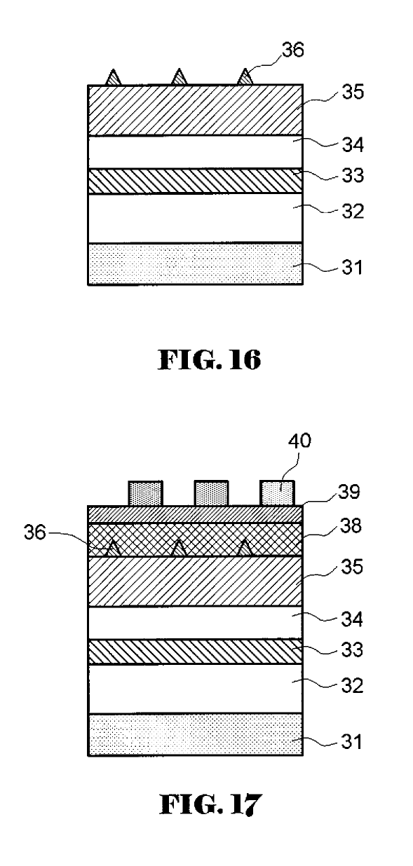

The layout of a first photomask used for the patterning of first photoresist layer 37 will be described with reference to a plan view in FIG. 14.

In FIG. 14, places where wiring layers 50 are formed in a subsequent step are shown by regions surrounded by a broken line for reference.

Reference numeral 41 denotes the light-blocking regions of the first photomask, which are formed in a plurality of strip-shaped patterns extending in the up and down direction (direction orthogonal to A-A′) in the drawing. Reference numeral 42 denotes the transmissive regions of the first photomask, which are formed in a plurality of strip-shaped patterns extending in the up and down direction (direction orthogonal to A-A′) in the drawing.

As shown in FIG. 14, light-blocking regions 41 are provided at positions corresponding to alternate wiring layers 50 to be finally formed. Also, the width of light-blocking region 41 in the direction of A-A′ is located to be wider than the width of wiring layer 50 to be formed.

By performing exposure and development using the first photomask, first photoresist layer 37 at positions corresponding to light-blocking regions 41 remains, and first photoresist layer 37 at positions corresponding to transmissive regions 42 is removed, thereby, the pattern of first photoresist layer 37 is formed, as shown in FIG. 15.

Next, dry etching is performed using the pattern of first photoresist layer 37 as a mask, and the patterning of first ARL 36 is performed, as shown in FIG. 16. At this time, the etching selection ratio between first ARL 36 and first photoresist layer 37 is decreased, and the etching of first photoresist layer 37 is also allowed to proceed in the lateral direction. Thus, first ARL 36 can remain in tapered shapes, as shown in FIG. 16, and first ARL 36 with a dimension (the width of the bottom surface portions) smaller than the pattern width of first photoresist layer 37 can be formed. Note that first ARL 36 need not be in complete tapered shapes, and only portions near the upper surface of first ARL 36 may be tapered.

In this etching, the etching of first photoresist layer 37 also proceeds, and first photoresist layer 37 is removed simultaneously with etching. The remaining first photoresist layer 37 may be removed by stripping treatment using a chemical solution, such as a sulfuric acid-hydrogen peroxide mixture (H₂SO₄/H₂O₂).

As shown in FIG. 14, the layout of the first photomask can be such that both the width and interval of lines to be formed are larger than those of wiring layers 50 desired to be finally formed (FIG. 12). For example, first photoresist layer 37 with a width of 50 nm can be formed with respect to the width of the wiring layer desired to be formed, 25 nm. In addition, first photoresist layer 37 may have mask resistance enough to etch first ARL 36, and therefore, by making the photoresist layer thinner, even a fine pattern can be easily formed. Using a first photomask laid out so that the pattern dimension of first photoresist layer 37 is the same as the width of wiring desired to be formed, first ARL 36 may be processed without side-etching first photoresist layer 37. Also in this case, a high-resolution photoresist suitable for a fine pattern formation can be used, and therefore, even a fine pattern can be easily formed.

Next, as shown in FIG. 17, second carbon layer 38 with a thickness of about 100 nm is deposited so as to cover first ARL 36. By forming at least the vicinity of the upper surface of first ARL 36 in tapered shapes, second carbon layer 38 can be easily deposited so as to suppress the formation of cavities (voids) and the like and fill the space portions of adjacent first ARL 36.

Second ARL 39 with a thickness of about 50 nm is deposited on second carbon layer 38.

Second ARL 39 is coated with second photoresist layer 40, and patterning is performed using photolithography technique. A chemically-amplified photoresist with photosensitivity to ArF excimer laser light can be used for second photoresist layer 40.

Also, the difference in level in the base is reduced by the deposition of second carbon layer 38, and therefore, the pattern formation of second photoresist layer 40 is easy.

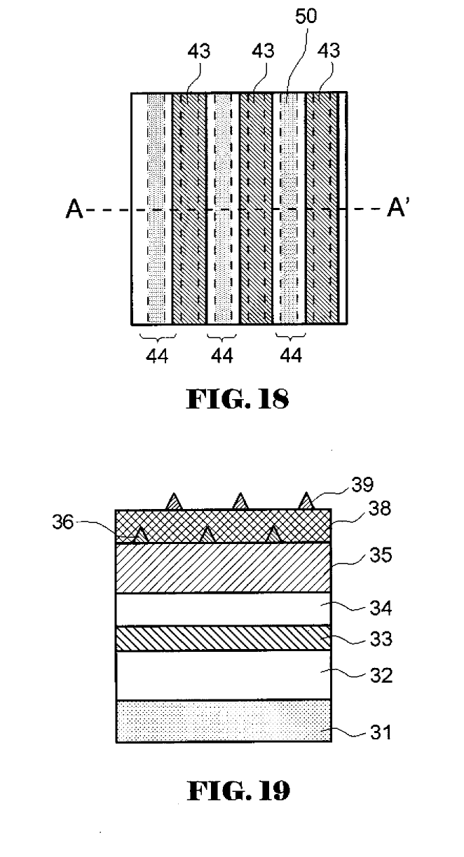

The layout of a second photomask used for the patterning of second photoresist layer 40 will be described with reference to a plan view in FIG. 18.

In FIG. 18, places where wiring layers 50 are formed in a subsequent step are shown by regions surrounded by a broken line for reference.

Reference numeral 43 denotes the light-blocking regions of the second photomask, which are formed in a plurality of strip-shaped patterns extending in the up and down direction (direction orthogonal to A-A′) in the drawing. Reference numeral 44 denotes the transmissive regions of the second photomask, which are formed in a plurality of strip-shaped patterns extending in the up and down direction (direction orthogonal to A-A′) in the drawing.

As shown in FIG. 18, light-blocking regions 43 are provided at positions corresponding to alternate wiring layers 50 to be finally formed. Also, the width of light-blocking region 43 in the direction of A-A′ is located to be wider than the width of wiring layer 50 to be formed. Light-blocking regions 43 are provided at the positions of the transmissive regions 42 of the first photomask (FIG. 14).

By performing exposure using the second photomask and development, second photoresist layer 40 at positions corresponding to light-blocking regions 43 remains, and second photoresist layer 40 at positions corresponding to transmissive regions 44 is removed, thereby, the pattern of second photoresist layer 40 is formed, as shown in FIG. 17.

Next, as shown in FIG. 19, dry etching is performed using the pattern of second photoresist layer 40 as a mask, and the patterning of second ARL 39 is performed. At this time, the etching selection ratio between second ARL 39 and second photoresist layer 40 is decreased, and the etching of second photoresist layer 40 is also allowed to proceed in the lateral direction. Thus, second ARL 39 can remain so as to have a width narrower than the width of second photoresist layer 40, as shown in FIG. 19.

As shown in FIG. 18, the layout of the second photomask can be such that both the width and interval of lines to be formed are larger than those of wiring layers 50 desired to be finally formed (FIG. 12) (for example, second photoresist layer 40 with a width of 50 nm can be formed with respect to the width of the wiring layer desired to be formed, 25 nm). In addition, second photoresist layer 40 may have mask resistance enough to etch second ARL 39, and therefore, by making the photoresist layer thinner, even a fine pattern can be easily formed.

Using a second photomask laid out so that the dimension of second photoresist layer 40 is the same as the width of wiring desired to be formed, second ARL 39 may be processed without side-etching second photoresist layer 40. Also in this case, a high-resolution photoresist suitable for a fine pattern formation can be used, and therefore, even a fine pattern can be easily formed. Second photoresist layer 40 may remain because it is removed in a subsequent step.

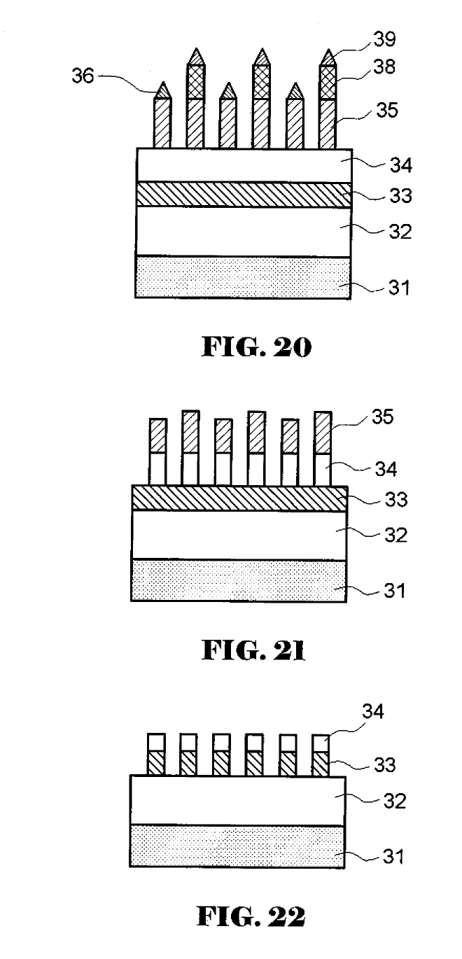

Next, dry etching is performed under conditions in which the carbon layers can be selectively removed using the first and second ARLs (36 and 39) as masks, to remove second carbon layer 38 and first carbon layer 35, as shown in FIG. 20. As shown in FIG. 20, with first ARL 36 serving as a mask in the portions of first ARL 36 exposed by removing second carbon layer 38, first carbon layer 35 in the lower layer is removed. Also when second photoresist layer 40 remains, the etching of second photoresist layer 40 proceeds in this etching, and second photoresist layer 40 is simultaneously removed.

Next, as shown in FIG. 21, the etching of silicon oxide layer 34 is performed using the first and second carbon layers (35 and 38) as masks.

In this etching, the etching of the ARLs also proceeds, and therefore, first ARL 36 and second ARL 39 are also removed.

Next, when the remaining first carbon layer 35 is removed by plasma ashing using O₂ gas, and then, metal layer 33 is anisotropically dry etched using linearly patterned silicon oxide layer 34 as a mask, the line pattern of metal layer 33 (wiring layers 50) is formed, as shown in FIG. 22.

Silicon oxide layer 34 used as the last hard mask may be left as it is as a surface protection layer for the wiring layers, or may be removed by adding an etching step.

As described above, in the present invention, the pattern of lines can be formed by the combinations of the hard masks (the carbon layer and the ARL) formed in twice. At this time, the photoresist layer used for the pattern formation of the hard mask may have only resistance to the etching of the ARL in the upper layer. Therefore, for the photoresist layer for fine processing that can be exposed by an ArF light source or the like, it is not necessary to form a thicker layer or add Si or the like to increase etching resistance, and the photoresist layer can be used with high resolution. Also, the difference in level in the base is reduced in the photoresist layer pattern formation for the second time, and therefore, the patterning of the photoresist layer is easier than conventional ones. Therefore, a pattern finer than conventional ones can be easily formed.

The formation method in this exemplary embodiment is suitably applied in forming a pattern in which a plurality of wiring layers extending in a predetermined direction, for example, the word lines or bit lines of a DRAM device, are located.

The pattern of the first photomask and the pattern of the second photomask need not necessarily be in straight line shapes and may be in partly curved line shapes located in parallel.

The modification applied to the first exemplary embodiment can also be applied to the second exemplary embodiment as it is.

Also, the thickness of the carbon layers and the ARLs is one example, and changes can be made without departing from the spirit of the present invention.

What is claimed is:

1. A pattern formation method comprising:
forming a first carbon layer on a first layer;
forming a first anti-reflecting layer on the first carbon layer;
forming a first photoresist pattern on the first anti-reflecting layer;
forming a pattern of the first anti-reflecting layer, using the first photoresist pattern as a mask;
forming a second carbon layer so as to cover the first anti-reflecting layer pattern and the first carbon layer;
forming a second anti-reflecting layer on the second carbon layer;
forming a second photoresist pattern on the second anti-reflecting layer;
forming the second anti-reflecting layer in a pattern comprising an opening region at least not overlapping the first anti-reflecting layer pattern, using the second photoresist pattern as a mask;
removing the second carbon layer, using the second anti-reflecting layer pattern as a mask;
removing the first carbon layer by using the second anti-reflecting layer pattern and the first anti-reflecting layer pattern exposed by removal of the second carbon layer as masks; and
etching the first layer by using the remaining first and second carbon layers as masks.

2. The pattern formation method according to claim 1, wherein the first and second anti-reflecting layer patterns are linearly formed.

3. The pattern formation method according to claim 2, wherein the first and second anti-reflecting layer patterns are linear patterns crossing each other, and a hole corresponding to an opening formed by overlap of the first and second anti-reflecting layer patterns is formed in the first layer.

4. The pattern formation method according to claim 2, wherein the first and second anti-reflecting layer patterns are parallel linear patterns not overlapping each other, and a groove pattern corresponding to a gap between the first and second anti-reflecting layer patterns is formed in the first layer.

5. The pattern formation method according to claim 4, wherein the first layer in which the groove pattern is formed is an oxide layer formed on a metal layer, the method further comprising etching the metal layer, using the oxide layer as a mask, to form a wiring layer.

6. The pattern formation method according to claim 1, wherein at least the first anti-reflecting layer pattern has a tapered shape that narrows toward an upper portion.

7. The pattern formation method according to claim 1, wherein the first and second anti-reflecting layer patterns are formed in patterns narrower than the initial width of the first and second photoresist patterns by side-etching the corresponding first and second photoresist patterns respectively.

8. The pattern formation method according to claim 1, wherein the first and second anti-reflecting layer include a silicon oxynitride layer.

9. A pattern formation method comprising:
forming a first carbon layer on a first layer;
forming a first anti-reflecting layer on the first carbon layer;
forming a first photoresist pattern on the first anti-reflecting layer;
forming a pattern of the first anti-reflecting layer, using the first photoresist pattern as a mask;
forming an organic coating layer by spin coating so as to cover the first anti-reflecting layer pattern and the first carbon layer;
forming a second anti-reflecting layer on the organic coating layer;
forming a second photoresist pattern on the second anti-reflecting layer;
forming the second anti-reflecting layer in a pattern comprising an opening region at least not overlapping the first anti-reflecting layer pattern, using the second photoresist pattern as a mask;
removing the organic coating layer, using the second anti-reflecting layer pattern as a mask;
removing the first carbon layer by using the second anti-reflecting layer pattern and the first anti-reflecting layer pattern exposed by removal of the organic coating layer as masks; and
etching the first layer by using the remaining first carbon layer and the organic coating layer as masks.

10. The pattern formation method according to claim 9, wherein the first and second anti-reflecting layer patterns are linearly formed.

11. The pattern formation method according to claim 10, wherein the first and second anti-reflecting layer patterns are linear patterns crossing each other, and a hole corresponding to an opening formed by overlap of the first and second anti-reflecting layer patterns is formed in the first layer.

12. The pattern formation method according to claim 10, wherein the first and second anti-reflecting layer patterns are parallel linear patterns not overlapping each other, and a groove pattern corresponding to a gap between the first and second anti-reflecting layer patterns is formed in the first layer.

13. The pattern formation method according to claim 12, wherein the first layer in which the groove pattern is formed is an oxide layer formed on a metal layer, the method further comprising etching the metal layer, using the oxide layer as a mask, to form a wiring layer.

14. The pattern formation method according to claim 9, wherein at least the first anti-reflecting layer pattern has a tapered shape that narrows toward an upper portion.

15. The pattern formation method according to claim 9, wherein the first and second anti-reflecting layer patterns are formed in patterns narrower than the initial width of the first and second photoresist patterns by side-etching the corresponding first and second photoresist patterns respectively.

16. The pattern formation method according to claim 9, wherein the first and second anti-reflecting layer include a silicon oxynitride layer.

17. A pattern formation method comprising:
forming a first mask layer on a first layer;
forming a first anti-reflecting layer on the first mask layer;
forming a first photoresist pattern on the first anti-reflecting layer;
forming a pattern of the first anti-reflecting layer, using the first photoresist pattern as a mask;
forming a second mask layer so as to cover the first anti-reflecting layer pattern and the first mask layer;
forming a second anti-reflecting layer on the second mask layer;
forming a second photoresist pattern on the second anti-reflecting layer;
forming the second anti-reflecting layer in a pattern comprising an opening region at least not overlapping the first anti-reflecting layer pattern, using the second photoresist pattern as a mask;
removing the second mask layer, using the second anti-reflecting layer pattern as a mask;
removing the first mask layer by using the second anti-reflecting layer pattern and the first anti-reflecting layer pattern exposed by removal of the second mask layer as masks; and
removing the first layer by using the remaining first and second mask layers as masks.

18. The pattern formation method according to claim 17, wherein the first mask layer and the second mask layer include carbon.

19. The pattern formation method according to claim 18, wherein the first anti-reflecting layer and the second anti-reflecting layer include a silicon oxynitride layer.

20. The pattern formation method according to claim 18, wherein the first mask layer and the second mask layer is an amorphous carbon layer formed by plasma CVD method using hydrocarbon material.
